(19) United States
(12) Patent Application Publication
(10) Pub. No.: US 2007/0134435 A1
(43) Pub. Date: Jun. 14, 2007

(54) Method to improve the ashing/wet etch damage resistance and integration stability of low dielectric constant films

(76) Inventors: Sang H. Ahn, Santa Clara, CA (US); Alexandros T. Demos, Fremont, CA (US); Hichem M'Saad, Santa Clara, CA (US)

Correspondence Address: PATTERSON & SHERIDAN, LLP, 3040 POST OAK BOULEVARD, SUITE 1500, HOUSTON, TX, 77056, US

(21) Appl. No.: 11/304,847

(22) Filed: Dec. 13, 2005

(51) Int. Cl. C23C 16/00; C08J 7/04

(52) U.S. Cl. 427/515; 427/255.28

(57) ABSTRACT

A method for depositing a low dielectric constant film on a substrate in a chamber from a mixture including two organosilicon compounds is provided. The mixture may further include a hydrocarbon compound and an oxidizing gas. The first organosilicon compound has an average of one or more Si—C bonds per Si atom. The second organosilicon compound has an average number of Si—C bonds per Si atom that is greater than the average number of Si—C bonds per Si atom in the first organosilicon compound. The low dielectric constant film has good plasma/wet etch damage resistance, good mechanical properties, and a desirable dielectric constant.

### BACKGROUND OF THE INVENTION

1. Field of the Invention

Embodiments of the present invention generally relate to the fabrication of integrated circuits. More particularly, embodiments of the present invention relate to a process for depositing low dielectric constant films on substrates.

2. Description of the Related Art

Integrated circuit geometries have dramatically decreased in size since such devices were first introduced several decades ago. Since then, integrated circuits have generally followed the two year/half-size rule (often called Moore's Law), which means that the number of devices on a chip doubles every two years. Today's fabrication facilities are routinely producing devices having 0.13 μm and even 0.1 μm feature sizes, and tomorrow's facilities soon will be producing devices having even smaller feature sizes.

The continued reduction in device geometries has generated a demand for films having lower dielectric constant (k) values because the capacitive coupling between adjacent metal lines must be reduced to further reduce the size of devices on integrated circuits. In particular, insulators having low dielectric constants, less than about 4.0, are desirable. Examples of insulators having low dielectric constants include spin-on glass, fluorine-doped silicon glass (FSG), carbon-doped oxide, porous carbon-doped oxide, and polytetrafluoroethylene (PTFE), which are all commercially available.

More recently, low dielectric constant organosilicon films having k values less than about 3.5 have been developed. One method that has been used to develop low dielectric constant organosilicon films has been to deposit the films from a gas mixture comprising an organosilicon compound and a compound comprising thermally labile species or volatile groups and then post-treat the deposited films to remove the thermally labile species or volatile groups, such as organic groups, from the deposited films. The removal of the thermally labile species or volatile groups from the deposited films creates nanometer-sized voids in the films, which lowers the dielectric constant of the films, as air has a dielectric constant of approximately 1.

While low dielectric constant organosilicon films that have desirable low dielectric constants have been developed as described above, some of these low dielectric constant films have exhibited less than desirable mechanical properties, such as poor mechanical strength, which renders the films susceptible to damage during subsequent semiconductor processing steps. Semiconductor processing steps which can damage the low dielectric constant films include plasma-based processes, such as plasma cleaning steps that are often performed on patterned low dielectric constant films before a barrier or seed layer is deposited on the low dielectric constant films. Ashing processes to remove photoresists or bottom anti-reflective coatings (BARC) from the dielectric films and wet etch processes can also damage the films.

Thus, there remains a need for a process for making low dielectric constant films that have improved mechanical properties and chemical resistance to downstream plasma or wet etch processes.

### SUMMARY OF THE INVENTION

The present invention generally provides methods for depositing a low dielectric constant film. In one embodiment, the method includes introducing a first organosilicon compound into a chamber at a first flow rate, wherein the first organosilicon compound has an average of one or more Si—C bonds per Si atom, introducing a second organosilicon compound into the chamber at a second flow rate, wherein the second organosilicon compound has an average number of Si—C bonds per Si atom that is greater than the average number of Si—C bonds per atom in the first organosilicon compound, and wherein the second flow rate divided by the sum of the first flow rate and the second flow rate is between about 5% and about 50%, and reacting the first organosilicon compound and the second organosilicon compound in the presence of RF power to deposit a low dielectric constant film on a substrate in the chamber. An oxidizing gas may also be reacted with the first organosilicon compound and the second organosilicon compound. A low k dielectric film that is deposited using the first organosilicon compound, which has few Si—C bonds, typically has better mechanical properties than a low k dielectric film deposited using the second organosilicon compound with more Si—C bonds. However, the proportion of the second organosilicon precursor can be controlled to improve chemical resistance to plasma and wet etch processes with a minimal impact to the mechanical properties.

In another embodiment, the method includes introducing a first organosilicon compound into a chamber at a first flow rate, wherein the first organosilicon compound has an average of one or more Si—C bonds per Si atom, introducing a second organosilicon compound into the chamber at a second flow rate, wherein the second organosilicon compound has an average number of Si—C bonds per Si atom that is greater than the average number of Si—C bonds per atom in the first organosilicon compound, and wherein the second flow rate divided by the sum of the first flow rate and the second flow rate is between about 5% and about 50%, introducing a thermally labile compound into the chamber, and reacting the first organosilicon compound, the second organosilicon compound, and the thermally labile compound in the presence of RF power to deposit a low dielectric constant film on a substrate in the chamber. An oxidizing gas may also be reacted with the first organosilicon compound, the second organosilicon compound, and the thermally labile compound.

In a further embodiment, the method includes introducing methyldiethoxysilane into a chamber at a first flow rate, introducing trimethylsilane into the chamber at a second flow rate, wherein the second flow rate divided by the sum of the first flow rate and the second flow rate is between about 5% and about 50%, introducing alpha-terpinene into the chamber, and reacting the methyldiethoxysilane, trimethylsilane, and alpha-terpinene in the presence of RF power to deposit a low dielectric constant film on a substrate in the chamber. An oxidizing gas may also be reacted with the methyldiethoxysilane, trimethylsilane, and alpha-terpinene.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a graph showing film composition ratios (CHₓ/SiO, SiCH₃/SiO, Si—H/SiO) for low dielectric constant films deposited from precursor mixtures having different ratios of two organosilicon compound precursors according to embodiments of the invention.

FIG. 2 is a graph showing the dielectric constant and shrinkage of low dielectric constant films deposited from precursor mixtures having different ratios of two organosilicon compound precursors according to embodiments of the invention.

FIG. 3 is a graph showing the stress and modulus of low dielectric constant films deposited from precursor mixtures having different ratios of two organosilicon compound precursors according to embodiments of the invention.

### DETAILED DESCRIPTION

The present invention provides a method of depositing a low dielectric constant film comprising silicon, oxygen, and carbon by reacting a first organosilicon compound and a second organosilicon compound in a chamber at conditions sufficient to deposit a low dielectric constant film. The low dielectric constant film typically has a dielectric constant of about 3.0 or less, preferably about 2.5 or less. The film may be deposited using plasma enhanced chemical vapor deposition (PECVD) in a chamber capable of performing chemical vapor deposition (CVD). The plasma may be generated using constant radio frequency (RF) power, pulsed RF power, high frequency RF power, dual frequency RF power, combinations thereof, or other plasma generation techniques.

The first organosilicon compound has an average of one or more Si—C bonds per Si atom. In one aspect, the first organosilicon compound comprises at least one Si—O bond, e.g., two Si—O bonds, a Si—C bond, and a Si—H bond. An organosilicon compound comprising at least one Si—O bond, a Si—C bond, and a Si—H bond is desirable because it was found that Si—O bonds in deposited dielectric films enhance networking with Si—H bonds, while Si—CH₃ bonds in deposited dielectric films contribute to a low dielectric constant and enhance the films' resistance to plasma and wet etch damage. Examples of compounds that may be used as the first organosilicon compound are the following: methyldiethoxysilane (mDEOS, CH₃—SiH—(OCH₂CH₃)₂), 1,3-dimethyldisiloxane (CH₃—SiH₂—O—SiH₂—CH₃), 1,1,3,3-tetramethyldisiloxane (((CH₃)₂—SiH—O—SiH—(CH₃)₂), bis(1-methyldisiloxanyl)methane ((CH₃—SiH₂—O—SiH₂—)₂—(CH₂), and 2,2-bis(1-methyldisiloxanyl)propane (CH₃—SiH₂—O—SiH₂—)₂—C(CH₃)₂.

The second organosilicon compound has an average number of Si—C bonds per Si atom that is greater than the average number of Si—C bonds per Si atom in the first organosilicon compound. For example, if methyldiethoxysilane, which has one Si—C bond per Si atom, is used as the first organosilicon compound, the second organosilicon compound has two or more Si—C bonds per Si atom. For example, the second organosilicon compound may be trimethylsilane, which has three Si—C bonds per Si atom.

Examples of compounds that may be used as the second organosilicon compound are the following: dimethylsilane ((CH₃)₂—SiH₂), trimethylsilane (TMS, (CH₃)₃—SiH), tetramethylsilane ((CH₃)₄—Si), phenylsilanes such as (C₆H₅)_{y}SiH_{4-y} with y being 2-4, vinylsilanes such as (CH₂═CH)_{z}SiH_{4-z} with z being 2-4, 1,1,3,3-tetramethyldisiloxane ((CH₃)₂—SiH—O—SiH—(CH₃)₂), hexamethyldisiloxane ((CH₃)₃—Si—O—Si—(CH₃)₃), (—O—Si—(CH₃)₂—)ₙ cyclic with n being 3 or greater such as hexamethyltrisiloxane, octamethylcyclotetrasiloxane (OMCTS), and decamethylpentasiloxane, dimethyldiethoxysilane ((CH₃)₂—Si—(OCH₃)₂), methylphenyldiethoxysilane ((CH₃)(C₆H₅)—Si—(OCH₃)₂), and partially fluorinated carbon derivatives thereof, such as CF₃—Si—(CH₃)₃.

Optionally, the first organosilicon compound and the second organosilicon compound are also reacted with an oxidizing gas. Oxidizing gases that may be used include oxygen (O₂), ozone (O₃), nitrous oxide (N₂O), carbon monoxide (CO), carbon dioxide (CO₂), water (H₂O), 2,3-butane dione, or combinations thereof. When ozone is used as an oxidizing gas, an ozone generator converts from 6% to 20%, typically about 15%, by weight of the ozone to the oxygen in a source gas, with the remainder typically being oxygen. However, the ozone concentration may be increased or decreased based upon the amount of ozone desired and the type of ozone generating equipment used. Disassociation of oxygen or the oxygen containing compounds may occur in a microwave chamber prior to entering the deposition chamber. Preferably, radio frequency (RF) power is applied to the reaction zone to increase dissociation.

Optionally, one or more carrier gases are introduced into the chamber in addition to the first and second organosilicon compounds. Examples of carrier gases that may be used include helium, argon, hydrogen, ethylene, and combinations thereof.

In one embodiment, one or more thermally labile compounds, e.g., one or more hydrocarbon compounds, are introduced into the chamber in addition to the first and second organosilicon compounds and the optional oxidizing gas and optional carrier gas. As defined herein, “hydrocarbon compounds” include hydrocarbons as well as hydrocarbon-based compounds that include other atoms in addition to carbon and hydrogen. The one or more hydrocarbon compounds are reacted with the first and second organosilicon compounds and the optional oxidizing gas to deposit a low dielectric constant film. The hydrocarbon compounds may include thermally labile species or volatile groups. The thermally labile species or volatile groups may be cyclic groups. The term “cyclic group” as used herein is intended to refer to a ring structure. The ring structure may contain as few as three atoms. The atoms may include carbon, nitrogen, oxygen, fluorine, and combinations thereof, for example. The cyclic group may include one or more single bonds, double bonds, triple bonds, and any combination thereof. For example, a cyclic group may include one or more aromatics, aryls, phenyls, cyclohexanes, cyclohexadienes, cycloheptadienes, and combinations thereof. The cyclic group may also be bi-cyclic or tri-cyclic. In one embodiment, the cyclic group is bonded to a linear or branched functional group. The linear or branched functional group preferably contains an alkyl or vinyl alkyl group and has between one and twenty carbon atoms. The linear or branched functional group may also include oxygen atoms, such as in a ketone, ether, and ester. Some exemplary compounds that may be used and have at least one cyclic group include alpha-terpinene (ATP), norbornadiene, vinylcyclohexane (VCH), and phenylacetate.

The first organosilicon compound may be introduced into the chamber at a flow rate between about 50 mgm and about 5000 mgm. The second organosilicon compound may be introduced into the chamber at a flow rate between about 5 sccm and about 1000 sccm. The flow rates of the first organosilicon compound and the second organosilicon compound are chosen such that the flow rate of the second organosilicon compound divided by the sum of the flow rate of the first organosilicon compound and the flow rate of the second organosilicon compound is between about 5% and about 50%. The relative flow rates of the first and second organosilicon compounds will be discussed further below.

The one or more optional oxidizing gases have a flow rate between about 50 and about 5,000 sccm, such as between about 100 and about 1,000 sccm, preferably about 200 sccm. The one or more optional hydrocarbon compounds are introduced to the chamber at a flow rate of about 100 to about 5,000 mgm, such as between about 500 and about 5,000 mgm, preferably about 3,000 mgm. The one or more optional carrier gases have a flow rate between about 500 sccm and about 5,000 sccm. Preferably, the first organosilicon compound is mDEOS, the second organosilicon compound is TMS, the hydrocarbon compound is alpha-terpinene, and the oxidizing gas is oxygen.

The flow rates described above and throughout the instant application are provided with respect to a 300 mm chamber having two isolated processing regions, such as a Producer® chamber, available from Applied Materials, Inc. of Santa Clara, Calif. Thus, the flow rates experienced per each substrate processing region are half of the flow rates into the chamber.

During deposition of the low dielectric constant film on the substrate in the chamber, the substrate is typically maintained at a temperature between about 25° C. and about 400° C. A power density ranging between about 0.07 W/Cm² and about 2.8 W/Cm², which is a RF power level of between about 50 W and about 2000 W for a 300 mm substrate is typically used. Preferably, the RF power level is between about 100 W and about 1500 W. The RF power is provided at a frequency between about 0.01 MHz and 300 MHz. The RF power may be provided at a mixed frequency, such as at a high frequency of about 13.56 MHz and a low frequency of about 350 kHz. The RF power may be cycled or pulsed to reduce heating of the substrate and promote greater porosity in the deposited film. The RF power may also be continuous or discontinuous.

After the low dielectric constant film is deposited, the film may be post-treated to remove thermally labile species or volatile groups, such as organic groups, from the deposited film. Post-treatments that may be used include electron beam treatments, UV treatments, thermal treatments (in the absence of an electron beam and/or UV treatment), and combinations thereof.

Exemplary electron beam conditions that may be used include a chamber temperature of between about 200° C. and about 600° C., e.g. about 350° C. to about 400° C. The electron beam energy may be from about 0.5 keV to about 30 keV. The exposure dose may be between about 1 μC/cm² and about 400 μC/cm². The chamber pressure may be between about 1 mTorr and about 100 mTorr. The gas ambient in the chamber may be any of the following gases: nitrogen, oxygen, hydrogen, argon, a blend of hydrogen and nitrogen, ammonia, xenon, or any combination of these gases. The electron beam current may be between about 0.15 mA and about 50 mA. The electron beam treatment may be performed for between about 1 minute and about 15 minutes. Although any electron beam device may be used, an exemplary electron beam chamber that may be used is an EBk™ electron beam chamber available from Applied Materials, Inc. of Santa Clara, Calif.

Exemplary UV post-treatment conditions that may be used include a chamber pressure of between about 1 Torr and about 10 Torr and a substrate support temperature of between about 350° C. and about 500° C. The UV radiation may be provided by any UV source, such as mercury microwave arc lamps, pulsed xenon flash lamps, or high-efficiency UV light emitting diode arrays. The UV radiation may have a wavelength of between about 170 nm and about 400 nm, for example. Further details of UV chambers and treatment conditions that may be used are described in commonly assigned U.S. patent application Ser. No. 11/124,908, filed on May 9, 2005, which is incorporated by reference herein. The NanoCure™ chamber from Applied Materials, Inc. is an example of a commercially available chamber that may be used for UV post-treatments.

An exemplary thermal post-treatment includes annealing the film at a substrate temperature between about 200° C. and about 500° C. for about 2 seconds to about 3 hours, preferably about 0.5 to about 2 hours, in a chamber. A non-reactive gas such as helium, hydrogen, nitrogen, or a mixture thereof may be introduced into the chamber at a rate of about 100 to about 10,000 sccm. The chamber pressure is maintained between about 1 mTorr and about 10 Torr. The preferred substrate spacing is between about 300 mils and about 800 mils. Annealing the low dielectric constant film at a substrate temperature of about 200° C. to about 500° C., preferably about 400° C. to about 420° C., after the low dielectric constant film is deposited volatilizes at least some of the organic groups in the film, forming nanometer-sized voids in the film.

The following example illustrates an embodiment of the invention. The substrate in the example was a 300 mm substrate. The low dielectric constant film was deposited on the substrate in a Producers chamber available from Applied Materials, Inc. of Santa Clara, Calif. While the low dielectric constant film was post-treated using e-beam, alternatively the low dielectric constant film can be cured thermally at 400° C. for 1 hour at a very low pressure in the mTorr range in an EBk™ electron beam chamber available from Applied Materials, Inc. of Santa Clara, Calif. or at 400° C. for 2 hours at a low pressure in the Torr range in a Producers chamber.

### EXAMPLE

A low dielectric constant film was deposited on a substrate at about 7.5 Torr and a temperature of about 260° C. The following processing gases and flow rates were used:

ATP, at 2900 mgm;

TMS, at 62 sccm;

mDEOS, at 1044 mgm (=186 sccm); and

Oxygen, at 200 sccm.

Thus, the film was deposited from a mixture having a TMS/mDEOS+TMS ratio of 25% (62 sccm TMS/186 sccm mDEOS+62 sccm TMS). The substrate was positioned about 300 mils from the gas distribution showerhead. A power level of 600 W at a frequency of 13.56 MHz was applied to the showerhead for plasma enhanced deposition of the films. The film had a dielectric constant (k) before post-treatment of about 2.8 as measured using SSM 5100 Hg CV measurement tool at 0.1 MHz. The substrate was then post-treated using e-beam under the following conditions: V_{acceleration}=5 KeV, electron beam current of 1.5 mA, electron beam dose of 100 μC/cm². The low dielectric constant film on the substrate had the following properties after post-treatment: a stress of about 50 MPa, a hardness of 0.78 GPa, and a modulus of 5.4 GPa.

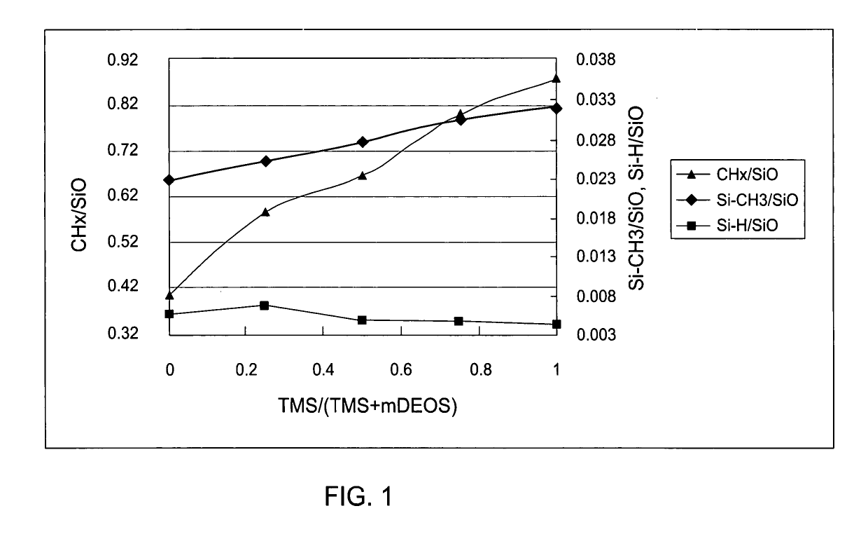

Further characterization of low dielectric constant films deposited according to embodiments of the invention will be provided with respect to the results shown in FIGS. 1-3. FIG. 1 is a graph showing the relative amounts of different bond types, including CHₓ/SiO, Si—CH₃/SiO, Si—H/SiO, in low dielectric constant films deposited using gas mixtures comprising mDEOS as the first organosilicon compound, TMS as the second organosilicon compound, alpha-terpinene, and oxygen. The relative amounts of the different bond types were estimated by the FTIR peak areas of the bonds in the deposited films after post-treatment. The films were deposited using different ratios of TMS flow rate/(TMS flow rate+mDEOS flow rate). FIG. 1 shows that the relative amount of Si—CH₃ bonds to SiO bonds in the films increases as the amount of TMS relative to the total amount of TMS and mDEOS in the gas mixture increases, while the relative amount of Si—H bonds to SiO bonds in the films decreases as the amount of TMS relative to the total amount of TMS and mDEOS in the gas mixture increases. The relative amount of CHx bonds to SiO bonds also increases as the amount of TMS relative to the total amount of TMS and mDEOS in the gas mixture increases. It is believed that the increased amount of Si—CH₃ bonds and the decreased amount of Si—H bonds in the films deposited according to embodiments of the invention compared to films deposited from one organosilicon precursor improves the films' resistance to undesirable water absorption.

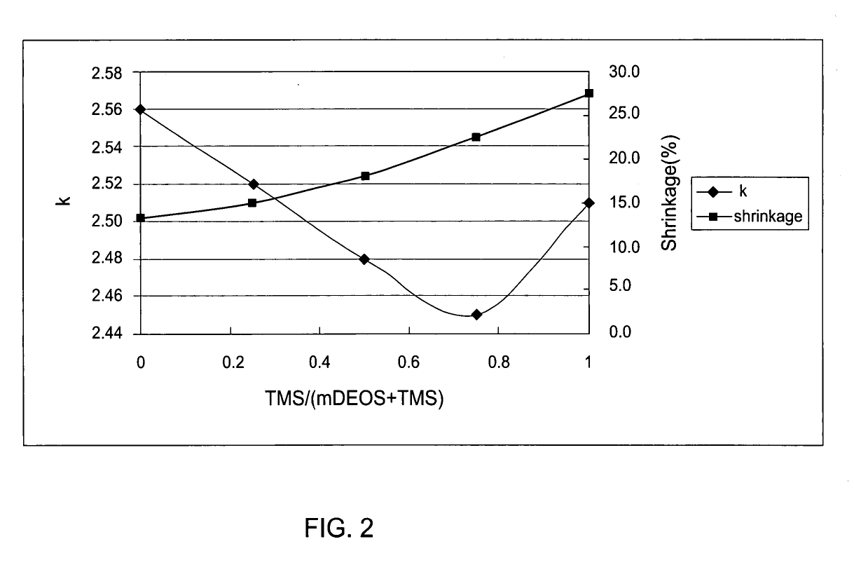

FIG. 2 is a graph showing the dielectric constant (k) and shrinkage of low dielectric constant films deposited from gas mixtures comprising mDEOS as the first organosilicon compound, TMS as the second organosilicon compound, alpha-terpinene, and oxygen. The films were deposited using different ratios of TMS flow rate/(TMS flow rate+mDEOS flow rate). FIG. 2 shows that films having a dielectric constant of 2.56 or less can be obtained according to embodiments of the invention and that the dielectric constant of the films increases as the amount of TMS relative to the total amount of TMS and mDEOS in the gas mixture increases. However, the shrinkage of the films increases as the amount of TMS relative to the total amount of TMS and mDEOS in the gas mixture increases. By choosing a TMS flow rate/(TMS flow rate+mDEOS flow rate) of between about 5% and about 50%, an acceptable combination of dielectric constant and mechanical properties can be obtained, in addition to better chemical resistance.

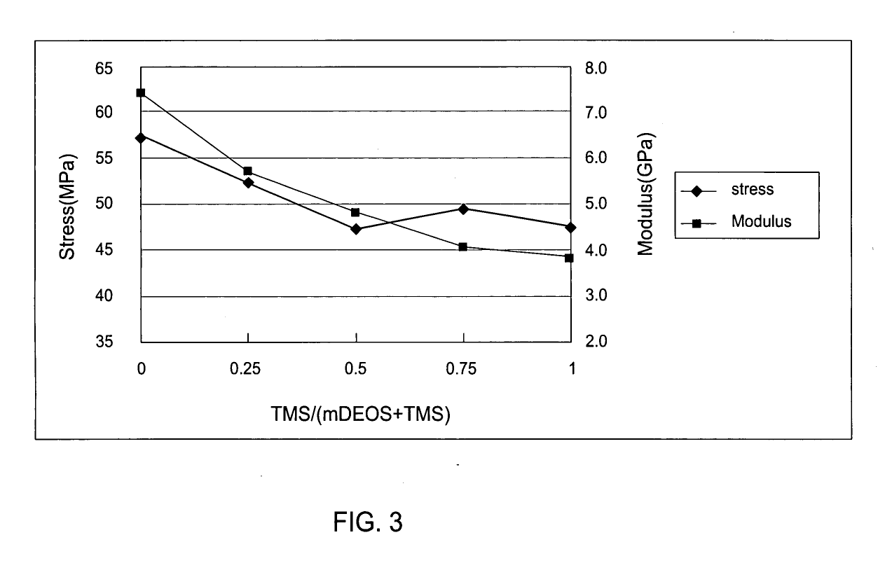

FIG. 3 is a graph showing the stress and modulus of low dielectric constant films deposited from gas mixtures comprising mDEOS as the first organosilicon compound, TMS as the second organosilicon compound, alpha-terpinene, and oxygen. The films were deposited using different ratios of TMS flow rate/(TMS flow rate+mDEOS flow rate). FIG. 3 shows that as the amount of TMS relative to the total amount of TMS and mDEOS in the gas mixture increases, the stress of the films decreases, which is desirable. However, the modulus of the films also decreases as the amount of TMS relative to the total amount of TMS and mDEOS in the gas mixture increases. By choosing a TMS flow rate/(TMS flow rate+mDEOS flow rate) of between about 5% and about 50%, an acceptable combination of film stress and modulus can be obtained.

It is believed that the increased amount of Si—CH₃ bonds in the films deposited with two organosilicon precursors relative to films deposited with one organosilicon precursor, i.e., films having a second organosilicon compound flow rate divided by the sum of a first organosilicon compound flow rate and the second organosilicon compound flow rate of 0 (See FIG. 1), enhances the films' resistance to plasma damage, such as from plasma cleaning steps, damage from ashing processes to remove photoresist or BARC, and damage from wet etching. By using a second organosilicon compound flow rate/sum of a first organosilicon compound flow rate and the second organosilicon compound flow rate equal to between about 5% and 50% to deposit a low dielectric constant film, an optimal combination of plasma/wet etch damage resistance, good mechanical properties, and a desirable dielectric constant can be obtained.

While the foregoing is directed to embodiments of the present invention, other and further embodiments of the invention may be devised without departing from the basic scope thereof, and the scope thereof is determined by the claims that follow.

What is claimed is:

1. A method for depositing a low dielectric constant film, comprising:
introducing a first organosilicon compound into a chamber at a first flow rate, wherein the first organosilicon compound has an average of one or more Si—C bonds per Si atom;
introducing a second organosilicon compound into the chamber at a second flow rate, wherein the second organosilicon compound has an average number of Si—C bonds per Si atom that is greater than the average number of Si—C bonds per Si atom in the first organosilicon compound, and wherein the second flow rate divided by the sum of the first flow rate and the second flow rate is between about 5% and about 50%; and
reacting the first organosilicon compound and the second organosilicon compound in the presence of RF power to deposit a low dielectric constant film on a substrate in the chamber.

2. The method of claim 1, wherein the first organosilicon compound comprises a Si—H bond.

3. The method of claim 1, wherein the first organosilicon compound comprises at least one Si—O bond, a Si—C bond, and a Si—H bond.

4. The method of claim 3, wherein the first organosilicon compound comprises two Si—O bonds.

5. The method of claim 1, wherein the second organosilicon compound comprises oxygen.

6. The method of claim 1, wherein the second organosilicon compound is selected from the group consisting of dimethylsilane, trimethylsilane, tetramethylsilane, (C₆H₅)_{y}SiH_{4-y} with y being 2-4, (CH₂═CH)_{z}SiH_{4-z} with z being 2-4, 1,1,3,3-tetramethyldisiloxane, hexamethyldisiloxane, hexamethyltrisiloxane, octamethylcyclotetrasiloxane, decamethylpentasiloxane, dimethyldiethoxysilane, methylphenyldiethoxysilane, CF₃—Si—(CH₃)₃, and partially fluorinated carbon derivatives thereof.

7. The method of claim 1, further comprising introducing an oxidizing gas into the chamber.

8. The method of claim 1, further comprising post-treating the low dielectric constant film with UV, an electron beam, a thermal post-treatment, or a combination thereof.

9. A method for depositing a low dielectric constant film, comprising:
introducing a first organosilicon compound into a chamber at a first flow rate, wherein the first organosilicon compound has an average of one or more Si—C bonds per Si atom;
introducing a second organosilicon compound into the chamber at a second flow rate, wherein the second organosilicon compound has an average number of Si—C bonds per Si atom that is greater than the average number of Si—C bonds per Si atom in the first organosilicon compound, and wherein the second flow rate divided by the sum of the first flow rate and the second flow rate is between about 5% and about 50%;
introducing a thermally labile compound into the chamber; and
reacting the first organosilicon compound, the second organosilicon compound, and the thermally labile compound in the presence of RF power to deposit a low dielectric constant film on a substrate in the chamber.

10. The method of claim 9, further comprising introducing an oxidizing gas into the chamber.

11. The method of claim 9, wherein the thermally labile compound is a hydrocarbon.

12. The method of claim 11, wherein the hydrocarbon is a cyclic hydrocarbon.

13. The method of claim 12, wherein the cyclic hydrocarbon is selected from the group consisting of alpha-terpinene, norbornadiene, vinylcyclohexane, and phenylacetate.

14. The method of claim 9, further comprising post-treating the low dielectric constant film with UV an electron beam, a thermal post-treatment, or a combination thereof.

15. The method of claim 9, wherein the first organosilicon compound comprises at least one Si—O bond, a Si—C bond, and a Si—H bond.

16. The method of claim 15, wherein the first organosilicon compound comprises two Si—O bonds.

17. A method for depositing a low dielectric constant film, comprising:
introducing methyldieothoxysilane into a chamber at a first flow rate;
introducing trimethylsilane into the chamber at a second flow rate, wherein the second flow rate divided by the sum of the first flow rate and the second flow rate is between about 5% and about 50%;
introducing alpha-terpinene into the chamber; and
reacting the methyldiethoxysilane, trimethylsilane, and alpha-terpinene in the presence of RF power to deposit a low dielectric constant film on a substrate in the chamber.

18. The method of claim 17, further comprising introducing an oxidizing gas into the chamber.

19. The method of claim 18, wherein the second flow rate divided by the sum of the first flow rate and the second flow rate is between about 10% and about 45%.

20. The method of claim 17, further comprising post-treating the low dielectric constant film with UV, an electron beam, a thermal post-treatment, or a combination thereof.
